(19) United States
(12) Patent Application Publication
(10) Pub. No.: US 2019/0312091 A1
(43) Pub. Date: Oct. 10, 2019

(54) DISPLAY DEVICE

(71) Applicant: Sharp Kabushiki Kaisha, Sakai City, Osaka (JP)

(72) Inventors: Shinsuke SAIDA, Sakai City (JP); Tohru OKABE, Sakai City (JP); Ryosuke GUNJI, Sakai City (JP); Hiroki TANIYAMA, Sakai City (JP); Shinji ICHIKAWA, Sakai City (JP); Yoshihiro NAKADA, Sakai City (JP); Hiroharu JINMURA, Sakai City (JP); Akira INOUE, Sakai City (JP)

(21) Appl. No.: 16/469,678

(22) PCT Filed: Sep. 28, 2017
(86) PCT No.: PCT/JP2017/035169

§ 371 Date: Jun. 14, 2019

(51) Int. Cl. H01L 27/32; H01L 51/52; H01L 51/56

(52) U.S. Cl. CPC H01L 27/3246; H01L 2227/323; H01L 51/56; H01L 51/5253

(57) ABSTRACT

A display device is provided that may prevent peeling of a sealing layer between a first partition and a second partition formed at an end portion of the sealing layer that seals a light emitting layer. An organic EL display device includes a sealing layer that is configured to seal a light emitting element layer and is doubly enclosed at an end portion by a first bank and a second bank that is formed more on the outer side than the first bank with a gap in between. An outer side wall surface of the first bank facing the second bank is formed as a gentle slope with an inclination angle smaller than an inner side wall surface of the first bank on the side opposite to the second bank.

### TECHNICAL FIELD

The disclosure relates to a display device in which a sealing layer that seals a light emitting layer is doubly enclosed with a first partition and a second partition at an end portion.

### BACKGROUND ART

For example, an organic EL display device 100 disclosed in PTL 1, as illustrated in FIG. 13A and FIG. 13B, has side surfaces of a bank 110 of a pixel 101 are formed with a large part of a circumference of each pixel formed as a cliff portion 111 with an inclination angle of 90° or greater, and with a part of the circumference of each pixel 101 formed as a gentle slope portion 112 with an inclination angle smaller than 90°.

This facilitates division of an organic layer 120 of the pixel 101 at the cliff portions 111 in the side surfaces of the bank 110, and formation of a recess that advantageously draws in monomer forming a flattening layer (not illustrated), in a process of forming a sealing layer (not illustrated) on the upper side. As a result, the flattening layer has a hem further shortened so that film peeling is less likely to occur.

An organic light emitting panel 200 disclosed in PTL 2 has, as illustrated in FIG. 14, a pixel portion 201a and a pixel portion 201b arranged with a non-pixel portion 202 provided therebetween. The pixel portion 201a is formed by applying sub pixels 201a1, 201a2, and 201a3, for forming an organic light emitting layer, in this order. The same is applied to the pixel portion 201b. The non-pixel portion 202 has no organic light emitting layer formed, and thus involves no application of ink therefor. The sub-pixel 201a3 of the pixel portion 201a is defined by a bank 211c and a bank 211d. The bank 211d has an inner wall surface 211d3 with an inclination angleθd3 that is larger than an inclination angleθc3 of an inner wall surface 211c3 of the bank 211c. On the other hand, a sub-pixel 100b1 of the pixel portion 201b is defined by a bank 211e and a bank 211f. The bank 211e has an inner wall surface 211e1 with an inclination angleθe1 that is equal to an inclination angleθf1 of an inner wall surface 211f1 of the bank 211f.

Thus, a difference in a pinning position of ink is provided so that a distribution gradient of a vapor concentration at the time of ink application is adjusted to facilitate an attempt to achieve a uniform thickness of the organic light emitting layer over the entire panel, whereby a display device with small unevenness in in-plane brightness is achieved.

### CITATION LIST

### Patent Literature

PTL 1: JP 2015-50022 A (published Mar. 16, 2015)

PTL 2: WO 2012/049718 (internationally published Apr. 19, 2012)

### SUMMARY

### Technical Problem

Some known display devices available on market has a sealing layer that seals a light emitting layer doubly enclosed at an end portion by a first partition and a second partition that is provided more on the outer side than the first partition with a gap in between. Such a known display device disadvantageously involves a high risk of the sealing layer peeling due to a steep wall surfaces of the first partition and the second partition, in a case where the first partition and the second partition are formed in the same step as the flattening film. Specifically, the gap between the first partition and the second partition is narrow, and the first partition formed on the inner side is generally shorter than the second partition formed on the outer side. This leads to small attachment force on the wall surface of the first partition facing the second partition, resulting in a higher risk of the sealing layer peeling.

PTL 1 and PTL 2 disclosing the known techniques have no description or indication on the wall surfaces of the first partition and the second partition.

An aspect of the disclosure is made in view of the disadvantage described above, and its object is to provide a display device that may prevent peeling of a sealing layer, formed between a first partition and a second partition at an end portion of the sealing layer for sealing a light emitting layer.

### Solution to Problem

In a display device according to one aspect of the disclosure is a display device including a sealing layer that is configured to seal a light emitting layer and is doubly enclosed at an end portion by a first partition and a second partition that is formed more on an outer side than the first partition with a gap in between, wherein an outer side wall surface of the first partition facing the second partition is formed as a gentle slope with an inclination angle smaller than an inclination angle of an inner side wall surface of the first partition on a side opposite to the second partition.

### Advantageous Effects of Disclosure

One aspect of the disclosure has an effect of providing a display device that may prevent peeling of a sealing layer, formed between a first partition and a second partition at an end portion of the sealing layer for sealing a light emitting layer.

### BRIEF DESCRIPTION OF DRAWINGS

FIG. 1A is a cross-sectional view illustrating a configuration of an EL display device according to the first embodiment of the disclosure, and illustrates a configuration of a first bank and a second bank of the EL display device. FIG. 1B is a plan view illustrating a configuration of a photomask for forming an outer side wall surface of the first bank.

FIG. 2A is a cross-sectional view illustrating the configuration of the EL display device and illustrates a configuration of a center portion of the EL device. FIG. 2B is a cross-sectional view illustrating the configuration of an end portion of the EL display device.

FIG. 3A is cross-sectional view illustrating a configuration of the second bank of the EL display device. FIG. 3B is a plan view illustrating a configuration of a photomask for forming the second bank.

FIG. 4 is a plan view illustrating a configuration of a first bank and a second bank of an EL display device according to the second embodiment of the disclosure, with a corner portion steeply inclined.

FIG. 5A is a cross-sectional view illustrating a configuration of the first bank and the second bank at the corner portion of the EL display device. FIG. 5B is a plan view illustrating a configuration of a photomask for forming an outer side wall surface of the first bank at the corner portion.

FIG. 6A is a cross-sectional view illustrating a configuration of the first bank and the second bank at a non-corner portion of the EL display device. FIG. 6B is a plan view illustrating a configuration of a photomask for forming an outer side wall surface of the first bank.

FIG. 7 is a plan view illustrating a configuration of a first bank and a second bank that are designed to be close to each other at a corner portion of an EL display device of the third embodiment of the disclosure.

FIG. 8A is a cross-sectional view illustrating a configuration of the first bank and the second bank at the corner portion of the EL display device. FIG. 8B is a plan view illustrating a configuration of a photomask for forming the outer side wall surface of the first bank at the corner portion.

FIG. 9A is a cross-sectional view illustrating a configuration of the first bank and the second bank at a non-corner portion of the EL display device. FIG. 9B is a plan view illustrating a configuration of a photomask for forming the outer side wall surface of the first bank at the non-corner portion.

FIG. 10 is a plan view illustrating a configuration of a first bank and a second bank that are designed to be have a wide gap in between at a corner portion of an organic EL display device of the fourth embodiment of the disclosure.

FIG. 11A is a cross-sectional view illustrating a configuration of the first bank and the second bank at the corner portion. FIG. 11B is a plan view illustrating a configuration of a photomask for forming an outer side wall surface of the first bank at the corner portion.

FIG. 12A is a cross-sectional view illustrating a configuration of the first bank and the second bank at the non-corner portion of the EL display device. FIG. 12B is a plan view illustrating a configuration of a photomask for forming the outer side wall surface of the first bank at the non-corner portion.

FIG. 13A is a plan view illustrating a configuration of a known organic EL display device. FIG. 13B is a cross-sectional view illustrating a configuration of a pixel of the known organic EL display device.

FIG. 14 is a cross-sectional view illustrating a configuration of a pixel of another known organic EL display device.

### DESCRIPTION OF EMBODIMENTS

### First Embodiment

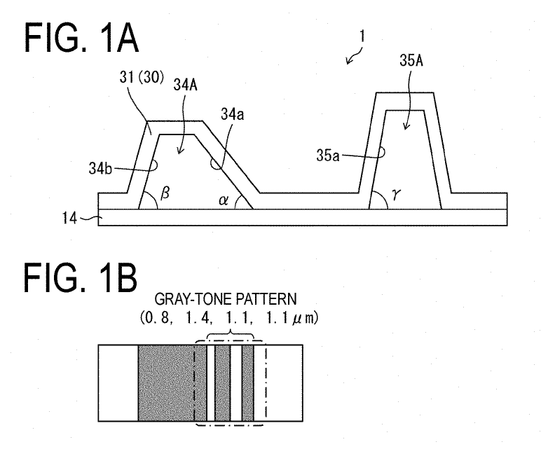

A description follows regarding one embodiment of the disclosure, with reference to FIGS. 1A to 3B.

### Basic Configuration of Organic EL Display Device

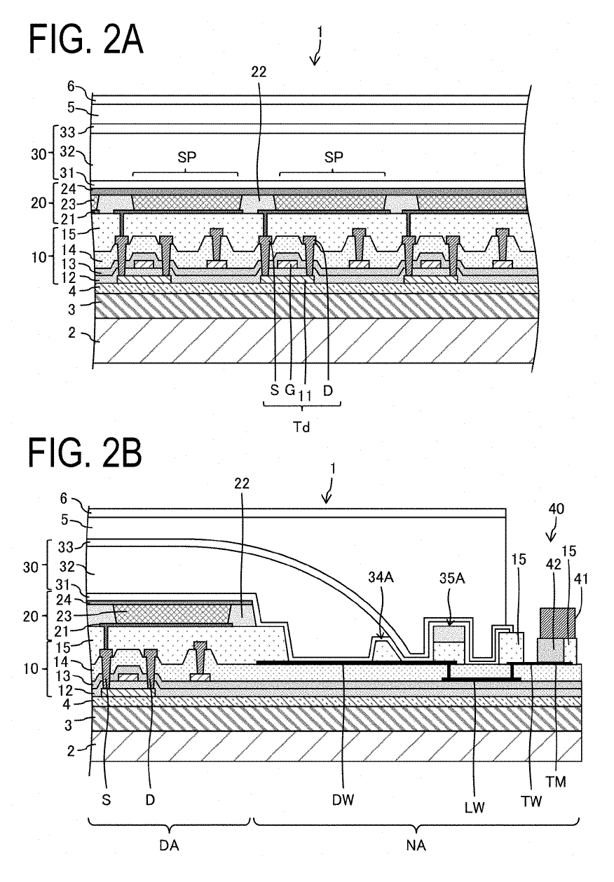

A configuration of an organic EL display device 1 as a display device according to the present embodiment is described based on FIGS. 2A and 2B. FIG. 2A is a cross-sectional view illustrating the configuration of a center portion of a pixel of the organic EL device of the present embodiment. FIG. 2B is a cross-sectional view illustrating the configuration of an end portion of the organic EL display device of the present embodiment.

The organic EL display device 1 of the present embodiment is a top-emission organic EL display device that emits light upward, and includes a base material 2, a resin layer 3, a barrier layer 4 (undercoat layer), a TFT layer 10, a light emitting element layer 20, a sealing layer 30, an adhesive layer 5, and a functional film 6 in this order from the lower side, as illustrated in FIG. 2A.

Examples of the material of the base material 2 include polyethylene terephthalate (PET). Examples of the material of the resin layer 3 include polymide, epoxy, and polyamide.

The barrier layer 4 is a layer for preventing moisture and impurities from reaching the TFT layer 10 and the light emitting element layer 20 during usage of the display device. The barrier layer 4 can be composed of, for example, a silicon oxide film, a silicon nitride film, a silicon oxynitride film, or a layered film thereof formed using a Chemical Vapor Deposition (CVD) method.

The TFT layer 10 includes a semiconductor film 11, an inorganic insulating film 12 formed on the semiconductor layer 11, a gate electrode G formed on the inorganic insulating film 12, an inorganic insulating film 13 formed on the gate electrode G, a capacity wiring line formed on the inorganic insulating film 13, an inorganic insulating film 14 formed on the capacity wiring line, a source electrode S and a drain electrode D formed on the inorganic insulating film 14, and a flattening film 15 formed on the source electrode S and the drain electrode D.

The semiconductor film 11, the inorganic insulating film 12 serving as a gate insulating film, and the gate electrode G form a thin film transistor Td that functions as a light emission control transistor. The source electrode S is connected to a source region of the semiconductor film 11, and the drain electrode D is connected to a drain region of the semiconductor film 11.

The semiconductor film 11 is formed of, for example, low temperature polysilicon (LTPS) or an oxide semiconductor. Note that although a TFT using the semiconductor film 11 as a channel is illustrated as a top gate structure in FIG. 2A and FIG. 2B, a bottom gate structure is also possible. For example, it is possible in the case where the channel of the TFT is an oxide semiconductor.

The inorganic insulating films 12, 13, and 14 can be constituted by a silicon oxide (SiOx) film or a silicon nitride (SiNx) film, or a layered film of these, formed using CVD. The flattening film (interlayer insulating film) 15 functions as an inter-layer insulating film can be constituted, for example, by a coatable photosensitive organic material, such as a polyimide, an acrylic, or the like.

The gate electrode G, the source electrode S, the drain electrode D, and the terminal are formed of a metal single layer film or a layered film including, for example, at least one of aluminum (Al), tungsten (W), molybdenum (Mo), tantalum (Ta), chromium (Cr), titanium (Ti), or copper (Cu).

A terminal portion 40 is provided on an end portion (a non-active region NA that does not overlap with the light emitting element layer 20) of the TFT layer 10. The terminal portion 40 includes a terminal TM that is used for connecting with an electronic circuit board 41 and a terminal wiring line TW that is connected to the terminal TM. The terminal wiring line TW is electrically connected to various wiring lines of the TFT layer 10 via a relay wiring line LW and a lead-out wiring line DW.

The electronic circuit board 41 is, for example, an IC chip or a flexible printed circuit board (FPC) mounted on the terminal TM via an anisotropic conductive material 42.

The terminal TM, the terminal wiring line TW, and the lead-out wiring line DW are formed in the same step as the source electrode S. Thus, these components are formed with the same material as the source electrode S, and on the inorganic insulating film 14 which is in the same layer as the source electrode S. Specifically, the components are formed of two titanium films and an aluminum film sandwiched by these films, for example.

The relay wiring line LW is formed in the same step as the capacitance electrode for example. End faces (edges) of the terminal TM, the terminal wiring line TW, and the lead-out wiring line DW are covered by the flattening film 15.

For example, the light emitting element layer 20 of the present embodiment is made from an organic light emitting diode layer, and includes an anode electrode 21 formed on the flattening film 15, a pixel bank 22 that defines a sub-pixel of an active region DA that overlaps with the light emitting element layer 20, a light emitting layer 23 formed on the anode electrode 21, and a cathode electrode 24 formed on the light emitting layer 23, and has an organic light emitting diode (OLED) formed that includes the anode electrode 21, the light emitting layer 23, and the cathode electrode 24 for example.

The pixel bank 22 covers the edge of the anode electrode 21, and the light emitting layer 23 is formed in an light emitting region, which is a region enclosed by the pixel bank 22, by vapor deposition or an ink-jet method. If the light emitting element layer 20 is an OLED layer, a hole injection layer, a hole transport layer, the light emitting layer 23, an electron transport layer, and an electron injection layer are layered in this order on the bottom surface of the pixel bank 22, that is, a portion where the anode electrode 21 is exposed. Here, the layers other than the light emitting layer 23 can serve as common layers.

The anode electrode 21 is photoreflective and is formed by the layering of Indium Tin Oxide (ITO) and an alloy containing Ag. The cathode electrode 24 can be constituted by a light-transmissive conductive material such as indium tin oxide (ITO) and indium zinc oxide (IZO).

In the case that the light emitting element layer 20 is the OLED layer, positive holes and electrons are recombined inside the EL layer 23 by a drive current between the anode electrode 21 and the cathode electrode 24, and light is emitted as a result of excitons that are generated by the recombination falling into a ground state. Since the cathode electrode 24 is light-transmissive and the anode electrode 21 is light-reflective, the light emitted from the EL layer 23 travels upwards and results in top emission.

The light emitting element layer 20 is not limited to OLED element configurations, and may be an inorganic light emitting diode or a quantum dot light emitting diode.

The sealing layer 30 is formed on the upper side of the light emitting element layer 20. The sealing layer 30 is light transmissive, and includes an inorganic sealing film 31 that covers the cathode electrode 24 of the light emitting element layer 20, the organic sealing film 32 formed on the inorganic sealing film 31, and an inorganic sealing film 33 that covers the organic sealing film 32.

The inorganic base films 31 and 33 may be made of a silicon oxide film, silicon nitride film, or silicon oxynitride film formed by CVD using a mask, or a layered film thereof, for example.

The organic sealing film 32 is thicker than the inorganic sealing films 31 and 33 and can be constituted by a coatable photosensitive organic material such as a polyimide, an acrylic, or the like. For example, after coating the inorganic sealing film 31 with an ink containing such an organic material using the ink-jet method, the ink is hardened by UV irradiation.

As a result, the sealing layer 30 covers the light emitting element layer 20 and inhibits foreign matter, such as water and oxygen, from infiltrating to the light emitting element layer 20.

The non-active region NA of the sealing layer 30 is provided with a first bank 34A and a second bank 35A defining edges of the organic sealing film 32. The first bank 34A is formed as a bulging body, and functions as a liquid stopper when the organic sealing film 32 is applied using an ink-jet method. The second bank 35A is formed as a bulging body, and is formed more on the outer side than the first bank 34A to function as a backup liquid stopper. Note that a lower portion of the second bank 35A is configured by the flattening film 15, and functions as a protection film for an end face of the lead-out wiring line DW. The pixel bank 22, the first bank 34A, and the second bank 35A may be formed in the same step, for example, using a coatable photosensitive organic material such as polyimide, epoxy, or acrylic.

The functional film 6 includes, for example, an optical compensation function, a touch sensor function, a protection function, or the like, and is adhered using the adhesive layer 5.

### Detailed Configuration of First Bank and Second Bank

As described above, in the organic EL display device 1 according to the present embodiment, the sealing layer 30, sealing the light emitting element layer 20 serving as a light emitting layer, is doubly enclosed at the end portion by the first bank 34A serving as a first partition and a second bank 35A serving as a second partition that is formed more on the outer side than the first bank 34A with a gap in between. This is because the sealing layer 30 has the configuration including the three layers of the inorganic sealing film 31, the organic sealing film 32, and the inorganic sealing film 33, which involves a risk of organic resin flowing over the first bank 34A in a step of forming the organic sealing film 32.

Still, in the desired scenario, the organic resin of the organic sealing film 32 is supposed to be stopped by the first bank 34A. When the organic resin of the organic sealing film 32 is stopped by the first bank 34A, the inorganic sealing films 31 and 33 are formed between the first bank 34A and the second bank 35A. Here, in such an organic EL display device 1, when the first bank 34A and the second bank 35A are formed in the same step as the flattening film, the first bank 34A and the second bank 35A have wall surfaces as steep slopes leading to a high risk of peeling of the inorganic sealing films 31 and 33 serving as the sealing layer 30. In particular, the gap between the first bank 34A and the second bank 35A is narrow. This results in low attraction force on a wall surface of the first bank 34A, facing the second bank 35A, which leads to a high risk of peeling of the inorganic sealing films 31 and 33 serving as the sealing layer 30.

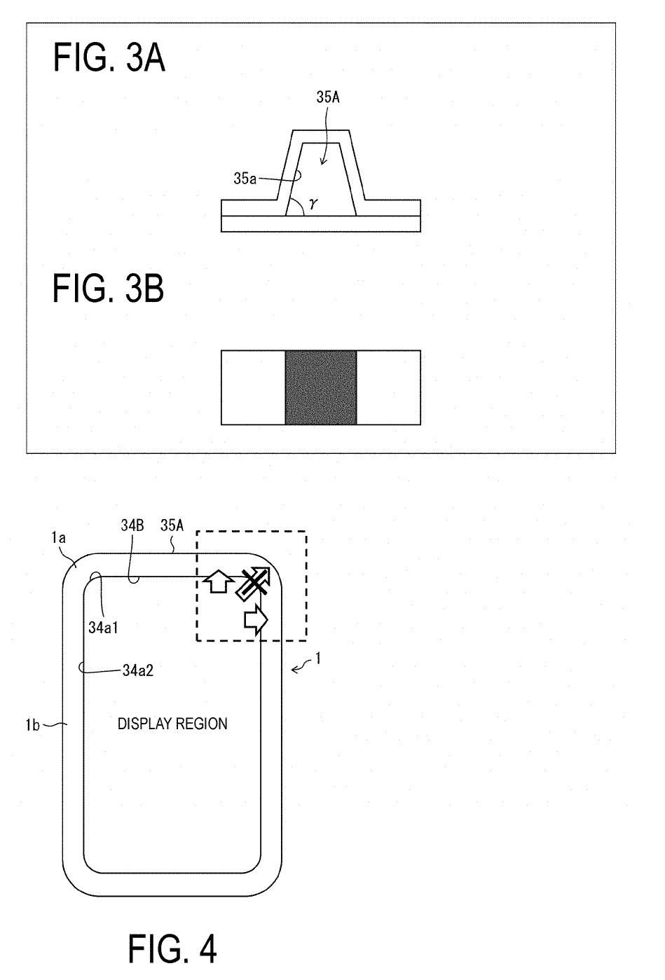

In view of this, the present embodiment features a structure of the first bank 34A and second bank 35A solving this problem. The configuration of the first bank 34A and the second bank 35A according to the present embodiment is described based on FIG. 1A, FIG. 1B, FIG. 3A, and FIG. 3B. FIG. 1A is a cross-sectional view illustrating a configuration of the first bank 34A and the second bank 35A of the organic EL display device 1 according to the present embodiment. FIG. 1B is a plan view illustrating a configuration of a photomask for forming an outer side wall surface 34a of the first bank 34A. FIG. 3A is a cross-sectional view illustrating the configuration of the second bank 35A of the organic EL display device 1. FIG. 3B is a plan view illustrating a configuration of a photomask for forming the second bank 35A.

In the organic EL display device 1 according to the present embodiment, as illustrated in FIG. 1A, the outer side wall surface 34a of the first bank 34A facing the second bank 35A is formed as a gentle slope with an inclination angle smaller than an inner side wall surface 34b of the first bank 34A on the side opposite to the second bank 35A.

With this structure, the outer side wall surface 34a of the first bank 34A facing the second bank 35A has a larger area so that an attachment region for the sealing layer 30 can be increased. As a result, the attachment area of the outer side wall surface 34a of the first bank 34A facing the second bank 35A is increased, whereby attachment force and adhesive force are increased.

Thus, the organic EL display device 1 can be provided that may prevent peeling of the sealing layer 30 between the first bank 34A and the second bank 35A formed in the end portion of the sealing layer 30 that seals the light emitting element layer 20.

As described above, the organic resin of the organic sealing film 32 serving as the sealing layer 30 is supposed to be stopped by the first bank 34A, but this is a desirable scenario, and the organic resin may flow over the first bank 34A in actual cases. In such a case, the organic resin needs to be prevented from further flowing over the second bank 35A. Various structures for preventing the organic resin from further flowing over the second bank 35A are described below.

For example, in the organic EL display device 1 according to the present embodiment, the second bank inner side wall surface 35a of the second bank 35A facing the first bank 34A has a larger inclination angle than the outer side wall surface 34a of the first bank 34A.

Thus, the second bank inner side wall surface 35a of the second bank 35A is provided as a steep slope, so that organic resin that has flowed over the first bank 34A serving as the first stopper can be prevented from further flowing over the second bank 35A serving as the second stopper, in the process of forming the sealing layer 30.

In the organic EL display device 1 according to the present embodiment, the second bank 35A is taller than the first bank 34A. With the second bank 35A thus being tall, the organic resin that has flowed over the first bank 34A serving as the first stopper can be prevented from flowing over the second bank 35A serving as the second stopper in the step of forming the sealing layer 30.

Now, how the side of the first bank 34A facing the second bank 35A is formed in the organic EL display device 1 according to the present embodiment will be described based on FIGS. 1A and 1B and FIGS. 3A and 3B.

First of all, the photomask illustrated in FIG. 3B is used for forming the second bank 35A illustrated in FIG. 3A.

In the present embodiment, the first bank 34A and the second bank 35A are made of the same material as the flattening film 15 including a coatable photosensitive organic material such as a polyimide, epoxy, or acrylic material. Thus, in the present embodiment, the flattening film 15 and the first and the second banks 34A and 35A are formed in the same step. In the present embodiment, for example, a what is known as a positive type photosensitive organic material is used, and thus the photomask is an exposure mask through which light passes to be incident on regions of the photosensitive organic material film to be removed. Note that what is known as a negative type photosensitive organic material film can also be used.

Thus, specifically, as illustrated in FIG. 2B, a photosensitive organic material such as a polyimide, epoxy, or acrylic material is coated on the inorganic insulating film 14 in the TFT layer 10 using an ink-jet method. Then, the coated surface, with the black part illustrated in FIG. 3B masked, is exposed to light from above via the photomask. Thus, white portions illustrated in FIG. 3B, corresponding to openings of the photomask, are exposed to light. Then, the photomask is removed and developing is performed so that the photosensitive organic material on the white portions on the coated surface corresponding to the openings of the photomask are dissolved to disappear, whereby the black part of the photomask remains. Thus, the flattening film 15 and the first and the second banks 34A and 35A are formed. The flattening film 15 and the first and the second banks 34A and 35A thus formed each have both end walls being steep slopes that are slightly inclined instead of being vertical walls.

Next, a method of forming the first bank 34A illustrated in FIG. 1A will be described.

The first bank 34A illustrated in FIG. 1A is formed by using the photomask illustrated in FIG. 1B. The photomask illustrated in FIG. 1B has a gray-tone pattern. Specifically, the gray-tone pattern is provided at a portion for forming the outer side wall surface 34a of the first bank 34A. The gray-tone pattern is what is known as a line & space pattern so that the photomask has lines and spaces alternately arranged. The photomask having the gray-tone pattern illustrated in FIG. 1B has white opening parts corresponding to the spaces and black shielded parts corresponding to the lines. In the present embodiment, the widths of the spaces and lines of the photomask, for example, are 0.8, 1.4, 1.4, 1.1, 1.1 μm from the apex of the first bank 34A toward the hem of the outer side wall surface 34a. Thus, the line & space form has the width changing in stages.

Thus, the exposure amount on the portion for forming the outer side wall surface 34a increases toward the hem of the outer side wall surface 34a. As a result, the exposure amount on the photosensitive organic material film increases toward the hem of the outer side wall surface 34a, and thus the dissolving amount of the photosensitive organic material film increases toward the hem of the outer side wall surface 34a. Thus, the outer side wall surface 34a can have a slope as a continuous gentle slope.

With such photomasks with gray-tone patterns having different pattern sizes and pattern pitches for the photomask having the gray-tone pattern with what is known as the line & space form, the outer side wall surface 34a can be adjusted to have a desired inclination angle without increasing the width of the first bank 34A.

In the present embodiment, the photomask with what is known as a line & space form to obtain the outer side wall surface 34a with a gentle slope is used. However, the photomask is not limited to the photomask with what is known as a line & space form. For example, the first bank 34A having the outer side wall surface 34a as a gentle slope can be obtained by using a photomask with what is known as a halftone form or by performing inclined exposure. The photomask with a halftone form is a photomask with a transmittance of the portion for forming the slope set to be half of that of the opening. The inclined exposure is a method of diagonally emitting light to make a difference in exposure intensity.

Now, the inclination angles of the outer side wall surface 34a and the inner side wall surface 34b of the first bank 34A, and of the second bank inner side wall surface 35a of the second bank 35A will be described.

As illustrated in FIG. 1A, the outer side wall surface 34a of the first bank 34A of the present embodiment has an inclination angle α that is equal to or smaller than 30° for example. The inner side wall surface 34b of the first bank 34A has an inclination angle 3 that is larger than 50°. With the inclination angle α of the outer side wall surface 34a of the first bank 34A thus being smaller than the inclination angle 3 of the inner side wall surface 34b of the first bank 34A, peeling of the sealing layer 30 between the first bank 34A and the second bank 35A can be prevented.

The second bank inner side wall surface 35a of the second bank 35A of the present embodiment has an inclination angle γ that is larger than 50°. Thus, the inclination angle γ of the second bank inner side wall surface 35a of the second bank 35A is larger than the inclination angle α of the outer side wall surface 34a of the first bank 34A. With this configuration, the organic resin that has flowed over the first bank 34A serving as the first stopper can be prevented from further flowing over the second bank 35A serving as the second stopper in the step of forming the sealing layer 30.

As described above, in the organic EL display device 1 according to the present embodiment, the sealing layer 30, sealing the light emitting element layer 20 serving as a light emitting layer, is doubly enclosed at the end portion by the first bank 34A serving as a first partition and a second bank 35A serving as a second partition that is formed more on the outer side than the first bank 34A with a gap in between. The outer side wall surface 34a of the first bank 34A facing the second bank 35A is formed as a gentle slope with an inclination angle smaller than the inner side wall surface 34b of the first bank 34A on the side opposite to the second bank 35A.

Thus, the outer side wall surface 34a of the first bank 34A has a larger area so that an attachment region for the sealing layer 30 can be increased. As a result, the attachment area of the outer side wall surface 34a of the first bank 34A increases, and the attachment force increases. Thus, the organic EL display device 1 can be provided that may prevent peeling of the sealing layer 30 between the first bank 34A and the second bank 35A formed in the end portion of the sealing layer 30 that seals the light emitting element layer 20.

In the organic EL display device 1 of the present embodiment, the second bank inner side wall surface 35a of the second bank 35A has a larger inclination angle than the outer side wall surface 34a of the first bank 34A. For example, the second bank inner side wall surface 35a has the inclination angle γ that is larger than 50° as described above, and the inclination angle α of the outer side wall surface 34a of the first bank 34A is equal to or smaller than 30° as described above.

Thus, the second bank inner side wall surface 35a is provided as a steep slope, so that the organic resin that has flowed over the first bank 34A can be prevented from further flowing over the second bank 35A, in the step of forming the sealing layer 30.

In the organic EL display device 1 according to the present embodiment, the second bank 35A is taller than the first bank 34A. With this configuration, the organic resin that has flowed over the first bank 34A serving as the first stopper can be prevented from further flowing over the second bank 35A serving as the second stopper in the step of forming the sealing layer 30.

### Second Embodiment

A description follows regarding another embodiment of the disclosure, with reference to FIGS. 4 to 6. The configuration other than that described in the present embodiment is the same as that in the first embodiment. For convenience of descriptions, members having the same functions as those of the members illustrated in the diagrams in the first embodiment described above are denoted by the same reference numerals, and descriptions thereof will be omitted.

The organic EL display device 1 of the present embodiment is unique in that in addition to the configuration of the organic EL display device 1 of the first embodiment, in the outer side wall surface 34a of a first bank 34B, a corner portion gentle slope in a corner portion 1a of a rectangular display region has a larger inclination angle than a non-corner portion gentle slope in a non-corner portion 1b of the rectangular display region. Thus, in the present embodiment, a structure of preventing the organic resin of the organic sealing film 32 serving as the sealing layer 30 that has flowed over the first bank 34B from further flowing over the second bank 35A is described.

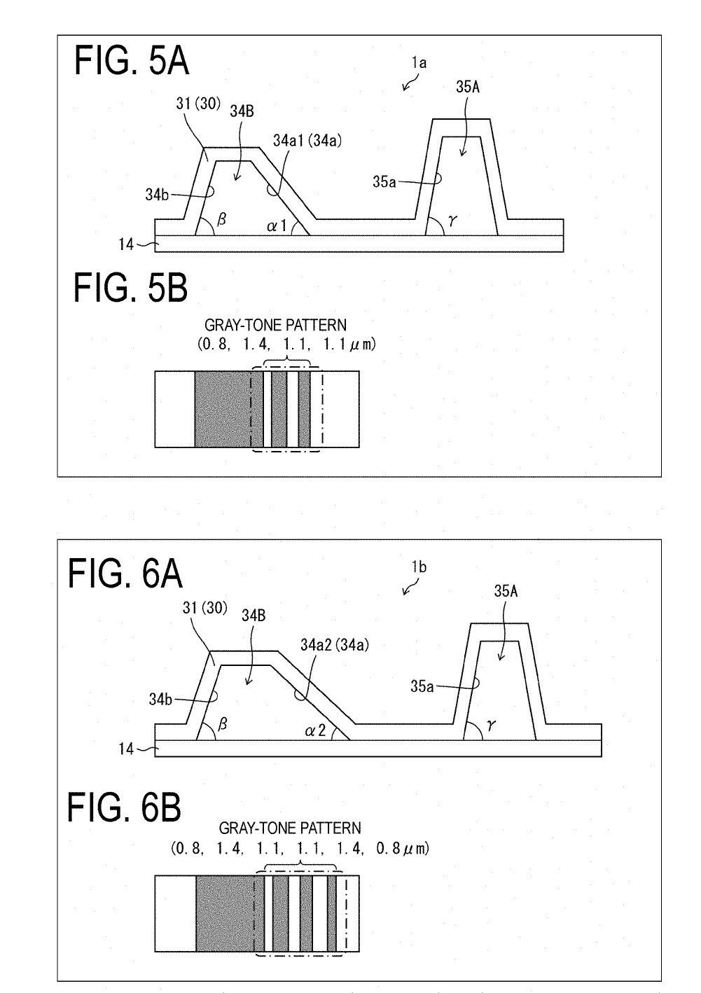

A configuration of the organic EL display device 1 according to the present embodiment is described based on FIG. 4 to FIGS. 6A and 6B. FIG. 4 is a plan view illustrating a configuration of the first bank 34B and the second bank 35A, in which the corner portion 1a of the organic EL display device 1 of the present embodiment is steeply inclined. FIG. 5A is a cross-sectional view illustrating a configuration of the first bank 34B and the second bank 35A at the corner portion 1a of the organic EL display device 1. FIG. 5B is a plan view illustrating a configuration of a photomask for forming a corner portion gentle slope 34a1 of the outer side wall surface 34a of the first bank 34B at the corner portion 1a. FIG. 6A is a cross-sectional view illustrating a configuration of the first bank 34B and the second bank 35A at the non-corner portion 1b of the organic EL display device 1. FIG. 6B is a plan view illustrating a configuration of a photomask for forming a non-corner portion gentle slope 34a2 at the outer side wall surface 34a of the first bank 34B.

As illustrated in FIG. 4, FIG. 5A, and FIG. 6A, in the gentle slope of the outer side wall surface 34a of the first bank 34B serving as the first partition of the present embodiment, the corner portion gentle slope 34a1 at the corner portion 1a of the rectangular display region has a larger inclination angle than the non-corner portion gentle slope 34a2 at the non-corner portion 1b of the rectangular display region.

Specifically, in a step of applying the organic resin to form the sealing layer 30, the organic resin may flow over the first bank 34B as indicated by arrows in FIG. 4. The gap between the first bank 34B and the second bank 35A is about 60 μm for example. For such an incident, in the organic EL display device 1 of the present embodiment, the corner portion gentle slope 34a1 of the first bank 34B at the corner portion 1a as illustrated in FIG. 5A is formed to be a steeper slope than the non-corner portion gentle slope 34a2 as illustrated in FIG. 6A.

Thus, in the step of forming the sealing layer 30, at the corner portion 1a of the rectangular display region, organic resin that has flowed over the first bank 34B is likely to flow into a space between the first bank 34B and the second bank 35A through the non-corner portion gentle slope 34a2. Thus, the organic resin can be prevented from flowing over the second bank 35A at the corner portion 1a.

As illustrated in FIG. 5A, an inclination angle α1 of the corner portion gentle slope 34a1 of the outer side wall surface 34a at the corner portion 1a of the first bank 34B of the present embodiment is from 20 to 30° for example. The widths of the spaces and lines of the photomask for forming the corner portion gentle slope 34a1 are, for example, 0.8, 1.4, 1.1, 1.1 μm from the apex of the first bank 34B toward the hem of the outer side wall surface 34a as illustrated in FIG. 5B. With the width of the line & space form thus changing in stages, the corner portion gentle slope 34a1 can have a large inclination angle.

As illustrated in FIG. 6A, an inclination angle α2 of the non-corner portion gentle slope 34a2 of the outer side wall surface 34a of the first bank 34B is from 10 to 20° for example. The widths of the spaces and lines of the photomask for forming the non-corner portion gentle slope 34a2 are, for example, 0.8, 1.4, 1.1, 1.1, 1.4, 0.8 μm from the apex of the first bank 34B toward the hem of the outer side wall surface 34a as illustrated in FIG. 6B.

Thus, the inclination angle α1 of the corner portion gentle slope 34a1 of the outer side wall surface 34a of the first bank 34B is larger than the inclination angle α2 of the non-corner portion gentle slope 34a2 of the outer side wall surface 34a of the first bank 34B. As a result, in the step of forming the sealing layer 30, at the corner portion 1a, organic resin that has flowed into a space between the first bank 34B and the second bank 35A is likely to flow toward the space between first bank 34B and the second bank 35A in the non-corner portion 1b, to be prevented from flowing over the second bank 35A.

The inclination angle β of the inner side wall surface 34b of the first bank 34B is the same as that in the first embodiment, and thus is larger than 50°.

In the present embodiment, the corner portion 1a and the non-corner portion 1b of the first bank 34B use the respective two types of photomasks with different widths of the spaces & lines. Still, in a practical application, for example, the first bank 34B and the second bank 35A can be formed by using a single photomask with the widths of the space and lines set to be different between regions of the corner portion 1a and the non-corner portion 1b for example.

### Third Embodiment

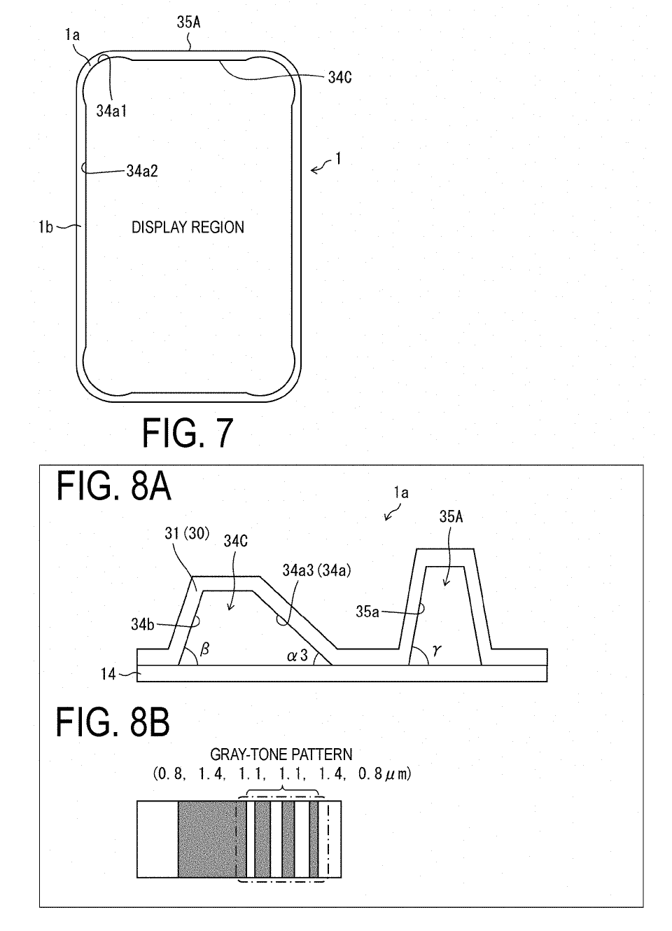

Further another embodiment of the disclosure will be described as follows, with reference to FIGS. 7 to 9B. The configuration other than that described in the present embodiment is the same as that in the first and the second embodiments. For convenience of descriptions, members having the same functions as those of the members illustrated in the diagrams in the first and the second embodiments described above are denoted by the same reference numerals, and descriptions thereof will be omitted.

The organic EL display device 1 of the present embodiment is unique in that in addition to the configuration of the organic EL display device 1 of the first embodiment, the gap between a first bank 34C and the second bank 35A at the corner portion 1a is set to be narrow. Thus, also in the present embodiment, a structure of preventing the organic resin of the organic sealing film 32 serving as the sealing layer 30 that has flowed over the first bank 34B from further flowing over the second bank 35A is described.

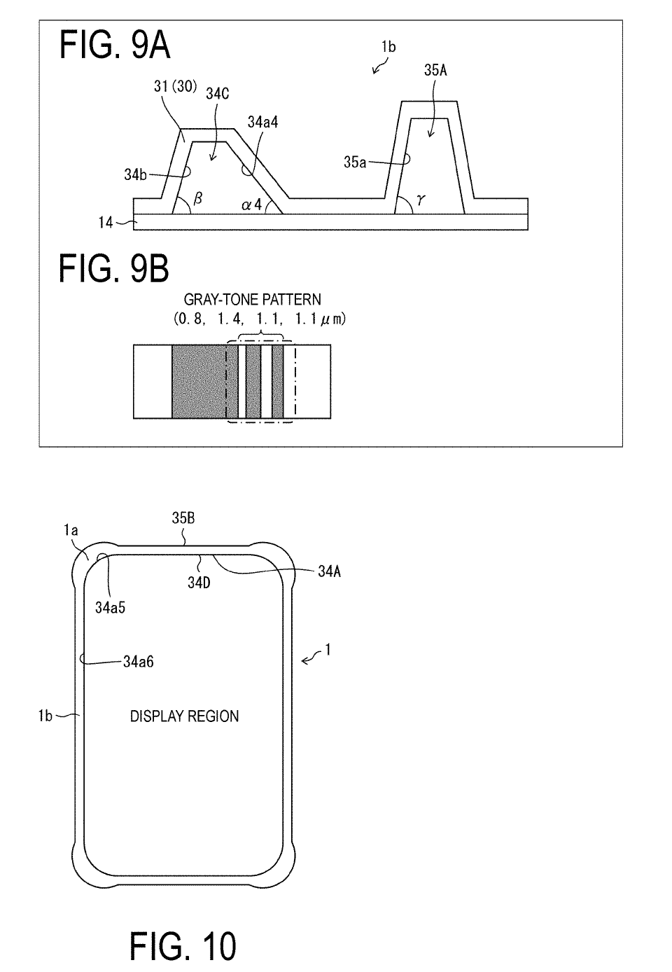

A configuration of the organic EL display device 1 according to the present embodiment is described based on FIG. 7 to FIGS. 9A and 9B. FIG. 7 is a plan view illustrating a configuration of the first bank 34C and the second bank 35A that are designed to be close to each other at the corner portion 1a of the organic EL display device 1 of the present embodiment. FIG. 8A is a cross-sectional view illustrating a configuration of the first bank 34C and the second bank 35A at the corner portion 1a of the organic EL display device 1. FIG. 8B is a plan view illustrating a configuration of a photomask for forming the outer side wall surface 34a of the first bank 34C at the corner portion 1a. FIG. 9A is a cross-sectional view illustrating a configuration of the first bank 34C and the second bank 35A at the non-corner portion 1b of the organic EL display device 1. FIG. 9B is a plan view illustrating a configuration of a photomask for forming the outer side wall surface 34a of the first bank 34C at the non-corner portion 1b.

In the organic EL display device 1 of the present embodiment, the gap between the first bank 34C and the second bank 35A is set to be narrower at the corner portion 1a than at the non-corner portion 1b. For example, the distance between the first bank 34C and the second bank 35A is about 20 am at the corner portion 1a and is about 60 am at the non-corner portion 1b.

Specifically, in a step of applying the organic resin to form the sealing layer 30, the organic resin may flow over the first bank 34C. Thus, for such an incident, in the organic EL display device 1 of the present embodiment, the gap between the first bank 34C and the second bank 35A is set to be narrower at the corner portion 1a than at the non-corner portion 1b as illustrated in FIG. 7.

Thus, at the corner portion 1a, organic resin that has flowed over the first bank 34C is likely to flow into a space between the first bank 34C and the second bank 35A at the non-corner portion 1b. Thus, the organic resin can be prevented from further flowing over the second bank 35A at the corner portion 1a.

As illustrated in FIG. 8A, an inclination angle α3 of a corner portion gentle slope 34a3 of the outer side wall surface 34a of the first bank 34C of the present embodiment is 10 to 200 for example. The widths of the spaces and lines of the photomask for forming the non-corner portion gentle slope 34a3 are, for example, 0.8, 1.4, 1.1, 1.1, 1.4, 0.8 m from the apex of the first bank 34C toward the hem of the outer side wall surface 34a, as illustrated in FIG. 8B.

As illustrated in FIG. 9A, an inclination angle α4 of a non-corner portion gentle slope 34a4 of the outer side wall surface 34a of the first bank 34C is from 20 to 30° for example. The widths of the spaces and lines of the photomask for forming the non-corner portion gentle slope 34a4 are, for example, 0.8, 1.4, 1.1, 1.1 μm from the apex of the first bank 34C toward the hem of the outer side wall surface 34a, as illustrated in FIG. 9B.

Thus, the inclination angle α3 of the corner portion gentle slope 34a3 of the outer side wall surface 34a of the first bank 34C is larger than the inclination angle α4 of the non-corner portion gentle slope 34a4 of the outer side wall surface 34a of the first bank 34C. Thus, sealing layer 30 can be prevented from peeling at the corner portion 1a.

The inclination angle β of the inner side wall surface 34b of the first bank 34C is the same as that in the first and the second embodiments, and thus is larger than 50°.

In the present embodiment, at the corner portion 1a, the gap between the first bank 34C and the second bank 35A is set to be narrow with the first bank 34C protruding outward. However, this should not necessarily be construed as a limiting sense in an aspect of the disclosure, and the second bank 35A may protrude inward for example.

### Fourth Embodiment

A description follows regarding a third embodiment of the disclosure, with reference to FIGS. 10 to 12. The configuration other than that described in the present embodiment is the same as that in the first to the third embodiments. For convenience of descriptions, members having the same functions as those of the members illustrated in the diagrams in the first to the third embodiments described above are denoted by the same reference numerals, and descriptions thereof will be omitted.

The organic EL display device 1 of the present embodiment is unique in that, in addition to the configuration of the organic EL display device 1 of the first embodiment, the gap between a first bank 34D and the second bank 35B is set to be wider at the corner portion 1a than at the non-corner portion 1b. Thus, also in the present embodiment, a structure of preventing the organic resin of the organic sealing film 32 serving as the sealing layer 30 that has flowed over the first bank 34D from further flowing over the second bank 35B is described.

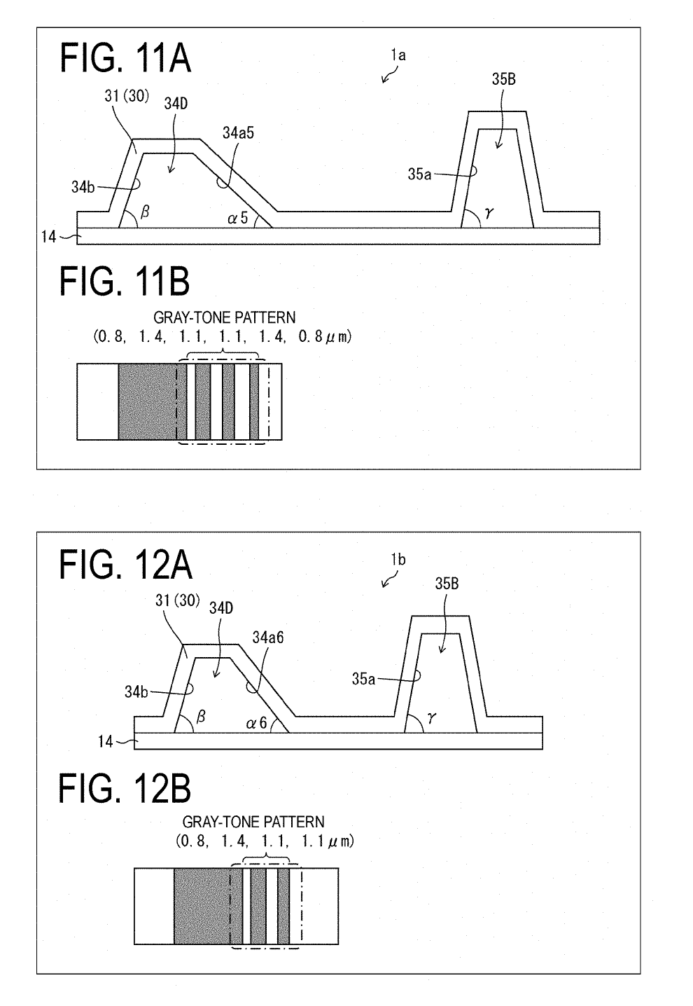

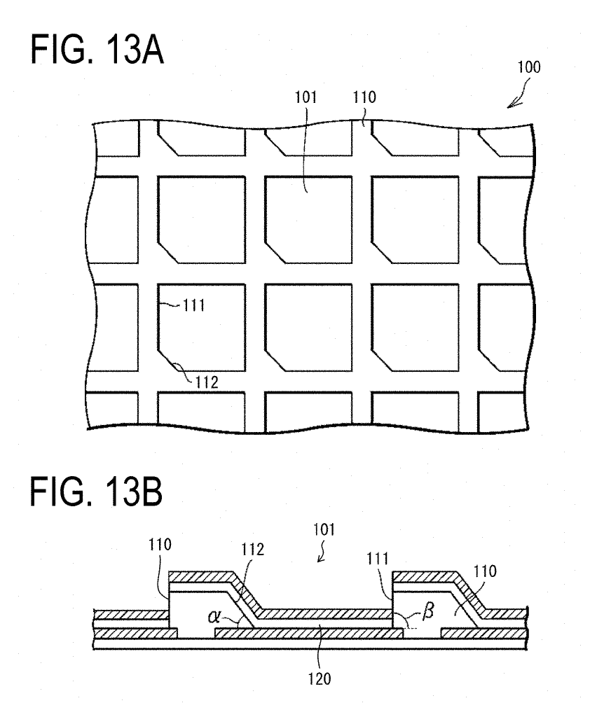

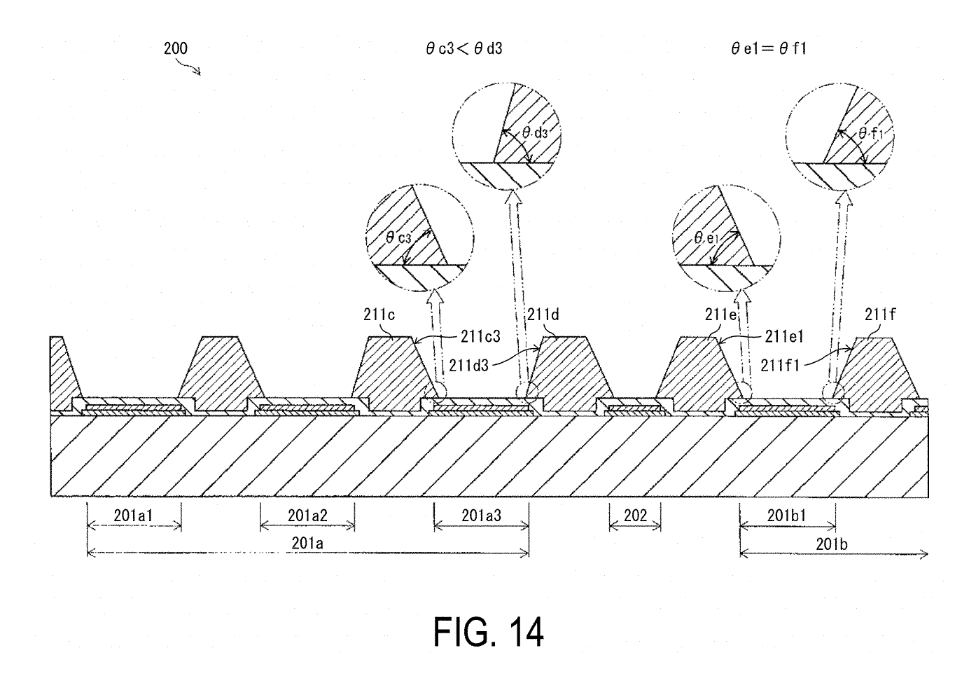

A configuration of the organic EL display device 1 according to the present embodiment is described based on FIG. 10 to FIGS. 12A and 12B. FIG. 10 is a plan view illustrating a configuration of the first bank 34D and the second bank 35B that are designed to be have a wide gap in between at the corner portion 1a of the organic EL display device 1 of the present embodiment. FIG. 11A is a cross-sectional view illustrating a configuration of the first bank 34D and the second bank 35B at the corner portion 1a of the organic EL display device 1. FIG. 11B is a plan view illustrating a configuration of a photomask for forming the outer side wall surface 34a of the first bank 34D at the corner portion 1a. FIG. 12A is a cross-sectional view illustrating a configuration of the first bank 34D and the second bank 35B at the non-corner portion 1b. FIG. 12B is a plan view illustrating a configuration of a photomask for forming the outer side wall surface 34a of the first bank 34D at the non-corner portion 1b.

In the organic EL display device 1 of the present embodiment, the gap between the first bank 34D and the second bank 35B is set to be wider at the corner portion 1a than at the non-corner portion 1b as illustrated in FIG. 10.

Specifically, in a step of applying the organic resin to form the sealing layer 30, the organic resin may flow over the first bank 34d. Thus, for such an incident, in the present embodiment, the gap between the first bank 34D and the second bank 35B is set to be wider at the corner portion 1a than at the non-corner portion 1b. For example, the gap between the first bank 34D and the second bank 35B is about 120 μm at the corner portion 1a and is about 60 μm at the non-corner portion 1b.

Thus, the gap between the first bank 34D and the second bank 35B at the corner portion 1a can serve as a reservoir for the organic resin. Thus, the organic resin can be prevented from flowing over the second bank 35B at the corner portion 1a.

In the organic EL display device 1 of the present embodiment in particular, the gap between the first bank 34D and the second bank 35B is set to be wider at the corner portion 1a than at the non-corner portion 1b with the second bank 35B protruding outward at the corner portion 1a.

Thus, the gap between the first bank 34D and the second bank 35B at the corner portion 1a may be widened with the first bank 34D set to protrude inward, for example. However, this may result in a smaller region area of the light emitting element layer 20.

In view of this, in the organic EL display device 1 of the present embodiment, the gap between the first bank 34D and the second bank 35B is set to be wider at the corner portion 1a than at the non-corner portion 1b with the second bank 35B protruding outward at the corner portion 1a.

Thus, the gap between the first bank 34D and the second bank 35B at the corner portion 1a can be widened without reducing the region area of the light emitting element layer 20. However, this should not necessarily be construed as a limiting sense in an aspect of the disclosure, and the first bank 34D may protrude inward for example.

As illustrated in FIG. 11A, an inclination angle α5 of a corner portion gentle slope 34a5 of the outer side wall surface 34a of the first bank 34D of the present embodiment is from 10 to 20° for example. The widths of the spaces and lines of the photomask for forming the non-corner portion gentle slope 34a5 are, for example, 0.8, 1.4, 1.1, 1.1, 1.4, 0.8 μm from the apex of the first bank 34D toward the hem of the outer side wall surface 34a, as illustrated in FIG. 11B.

As illustrated in FIG. 12A, an inclination angle α6 of a non-corner portion gentle slope 34a6 of the outer side wall surface 34a of the first bank 34D is from 20 to 30° for example. The widths of the spaces and lines of the photomask for forming the non-corner portion gentle slope 34a6 are, for example, 0.8, 1.4, 1.1, 1.1 μm from the apex of the first bank 34D toward the hem of the outer side wall surface 34a, as illustrated in FIG. 12B.

Thus, the inclination angle α5 of the corner portion gentle slope 34a5 of the outer side wall surface 34a of the first bank 34D at the corner portion 1a is smaller than the inclination angle α6 of the non-corner portion gentle slope 34a6 of the outer side wall surface 34a of the first bank 34D at the non-corner portion 1b. Thus, sealing layer 30 can be prevented from peeling at the corner portion 1a.

The inclination angle β of the inner side wall surface 34b of the first bank 34D is the same as that in the first to the third embodiments, and thus is larger than 50°.

The organic EL display device 1 is described as an example of a display device according to the present embodiment. The display device according to an aspect of the disclosure is not particularly limited, as long as it is a display panel including display elements. The display element mentioned above includes a display element having luminance or a transmittance controlled by current and a display element having luminance or a transmittance controlled by voltage. The display device controlled by current includes: an Electro Luminescence (EL) display device such as an organic EL display device including Organic Light Emitting Diodes (OLEDs), or an inorganic EL display device including inorganic light emitting diodes; and a Quantum dot Light Emitting Diode (QLED) display device including QLEDs. Furthermore, examples of a voltage-controlled display element include a liquid crystal display element.

### Supplement

In a display device (organic EL display device 1) according to a first aspect of the disclosure, which is a display device having a sealing layer 30, configured to seal a light emitting layer (light emitting element layer 20), doubly enclosed at an end portion by a first partition (first bank 34A to 34D) and a second partition (second bank 35A) that is formed more on an outer side than the first partition (first bank 34A to 34D) with a gap in between, in which an outer side wall surface 34a of the first partition (first bank 34A to 34D) facing the second partition (second bank 35A) is formed as a gentle slope with an inclination angle smaller than an inclination angle of an inner side wall surface 34b of the first partition (first bank 34A) on a side opposite to the second partition (second bank 35A).

With this configuration, a sealing layer that seals a light emitting layer is doubly enclosed at an end portion by a first partition and a second partition that is provided more on the outer side than the first partition with a gap in between. The sealing layer is generally formed with three layers including an inorganic sealing film, an organic sealing film, and an inorganic sealing film, and organic resin of the organic sealing film is preferably stopped at the first partition. When the organic resin of the organic sealing film is stopped by the first partition, the inorganic sealing film is formed between the first partition and the second partition. However, in such a display device, when the first partition and the second partition are formed in the same step as the flattening film, the first partition and the second partition have wall surfaces as steep slopes leading to a high risk of peeling of the inorganic sealing film serving as the sealing layer. Specifically, the gap between the first partition and the second partition is narrow, and the first partition formed on the inner side is generally shorter than the second partition formed on the outer side. This leads to small attachment force on the wall surface of the first partition facing the second partition, resulting in a higher risk of the inorganic sealing film serving as the sealing layer peeling.

In view of this, in the one aspect of the disclosure, the outer side wall surface of the first partition facing the second partition is formed as a gentle slope with an inclination angle smaller than the inner side wall surface of the first partition on the side opposite to the second partition. Thus, the outer side wall surface of the first partition facing the second partition has a larger area so that an attachment region for the inorganic sealing film serving as the sealing layer can be increased. As a result, the attachment area of the outer side wall surface of the first partition facing the second partition increases, and the attachment force increases.

Thus, the display device can be provided that may prevent peeling of the sealing layer between the first partition and the second partition formed in the end portion of the sealing layer that seals the light emitting element layer.

As described above, the organic resin of the organic sealing film serving as the sealing layer is supposed to be stopped by the first partition, but this is a desirable scenario, and the organic resin may flow over the first partition in actual cases. In such a case, the organic resin needs to be prevented from further flowing over the second partition. The following various aspects provide configurations for preventing the organic resin from further flowing over the second partition.

In the display device (organic EL display device 1) according to a second aspect of the disclosure, an inner side wall surface (second bank inner side wall surface 35a) of the second partition (second bank 35A) facing the first partition (first bank 34A to 34D) may have a larger inclination angle than the outer side wall surface (outer side wall surface 34a) of the first partition (first bank 34A to 34D).

Thus, the inner side wall surface of the second partition is provided as a steep slope, so that organic resin that has flowed over the first partition serving as the first stopper can be prevented from further flowing over the second partition serving as the second stopper, in the step of forming the sealing layer.

In the display device (organic EL display device 1) according to a third aspect of the disclosure, the second partition (second bank 35A) is preferably taller than the first partition (first bank 34A to 34D).

Thus, the inner side wall surface of the second partition is provided to be tall, so that organic resin that has flowed over the first partition serving as the first stopper can be prevented from further flowing over the second partition serving as the second stopper, in the step of forming the sealing layer.

In the display device (organic EL display device 1) according to a fourth aspect of the disclosure, the outer side wall surface of the first partition (first bank 34B) may have a corner portion gentle slope 34a1 at a corner portion 1a of a rectangular display region having a larger inclination angle than a non-corner portion gentle slope 34a2 at a non-corner portion 1b of the rectangular display region.

In a step of applying the organic resin to form the sealing layer, the organic resin may flow over the first partition. For such an incident, in the one aspect of the disclosure, the corner portion gentle slope of the first partition at the corner portion of the rectangular display region is formed to be a steeper slope than the non-corner portion gentle slope.

Thus, in the step of forming the sealing layer, at the corner portion of the rectangular display region, organic resin that has flowed over the first partition is likely to flow into a space between the first partition and the second partition at the non-corner portion of the rectangular display region. Thus, the organic resin can be prevented from flowing over the second partition at the corner portion of the rectangular display region.

In the display device (organic EL display device 1) according to a fifth aspect of the disclosure, the gap between the first partition (first bank 34C) and the second partition (second bank 35A) at the corner portion 1a of the rectangular display region may be narrower than the gap between the first partition (first bank 34C) and the second partition (second bank 35A) at the non-corner portion 1b of the rectangular display region. The gap between the first partition and the second partition may be set to be narrow with the first partition protruding outward or with the second partition protruding inward.

In a step of applying the organic resin to form the sealing layer, the organic resin may flow over the first partition. For such an incident, in the one aspect of the disclosure, the gap between the first partition and the second partition is narrower at the corner portion of the rectangular display region than at the non-corner portion of the rectangular display region.

Thus, at the corner portion of the rectangular display region, organic resin that has flowed over the first partition is likely to flow into a space between the first partition and the second partition at the non-corner portion of the rectangular display region. Thus, the organic resin can be prevented from flowing over the second partition at the corner portion of the rectangular display region.

In the display device (organic EL display device 1) according to a sixth aspect of the disclosure, the gap between the first partition (first bank 34C) and the second partition (second bank 35A) at the corner portion 1a of the rectangular display region may be wider than the gap between the first partition (first bank 34C) and the second partition (second bank 35A) at the non-corner portion 1b of the rectangular display region.

In a step of applying the organic resin to form the sealing layer, the organic resin may flow over the first partition. For such an incident, in the one aspect of the disclosure, the gap between the first partition and the second partition is wider at the corner portion of the rectangular display region than at the non-corner portion of the rectangular display region.

Thus, the gap between the first partition and the second partition at the corner portion of the rectangular display region can serve as a reservoir for the organic resin. Thus, the organic resin can be prevented from flowing over the second partition at the corner portion of the rectangular display region.

In the display device (organic EL display device 1) according to a seventh aspect of the disclosure, the gap between the first partition (first bank 34C) and the second partition (second bank 35A) at the corner portion 1a of the rectangular display region may be wider than the gap between the first partition (first bank 34C) and the second partition (second bank 35A) at the non-corner portion 1b of the rectangular display region, with the second partition (second bank 35B) protruding outward at the corner portion 1a of the rectangular display region.

Thus, the gap between the first partition and the second partition at the corner portion may be widened with the first partition set to protrude inward, for example. However, this may result in a smaller region area of the light emitting layer.

For such an incident, in the one aspect of the disclosure, the gap between the first partition and the second partition is set to be wider at the corner portion of the rectangular display region than at the non-corner portion of the rectangular display region, with the second partition protruding outward at the corner portion of the rectangular display region.

Thus, the gap between the first partition and the second partition at the corner portion of the rectangular display region can be widened without reducing the region area of the light emitting layer.

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

The display device according to an aspect of the disclosure is not particularly limited, as long as it is a display panel including display elements. The display element mentioned above includes a display element having luminance or a transmittance controlled by current and a display element having luminance or a transmittance controlled by voltage. The display device controlled by current includes: an Electro Luminescence (EL) display device such as an organic EL display device including Organic Light Emitting Diodes (OLEDs), or an inorganic EL display device including inorganic light emitting diodes; and a Quantum dot Light Emitting Diode (QLED) display device including QLEDs. Furthermore, examples of a voltage-controlled display element include a liquid crystal display element.

### REFERENCE SIGNS LIST

1 Organic EL display device (display device)
1a Corner portion
1b Non-corner portion
2 Base material
3 Resin layer
4 Barrier layer
5 Adhesive layer
6 Functional film
10 TFT layer
15 Flattening film
20 Light emitting element layer (light emitting layer)
30 Sealing layer
31, 33 Inorganic sealing film
32 Organic sealing film
34A to 34D First bank (first partition)
34a Outer side wall surface
34a1 Corner portion gentle slope
34a2 Non-corner portion gentle slope
34a3 Corner portion gentle slope
34a4 Non-corner portion gentle slope
34a5 Corner portion gentle slope
34a6 Non-corner portion gentle slope
34b Inner side wall surface
35A, 35B Second bank (second partition)
35a Second bank inner side wall surface
α to γ Inclination angle

1-3. (canceled)

4: A display device comprising:
a sealing layer, configured to seal a light emitting layer, doubly enclosed at an end portion by a first partition and a second partition that is formed more on an outer side than the first partition with a gap in between,
wherein an outer side wall surface of the first partition facing the second partition is formed as a gentle slope with an inclination angle smaller than an inclination angle of an inner side wall surface of the first partition on a side opposite to the second partition, and
the outer side wall surface of the first partition includes a corner portion gentle slope, at a corner portion of a rectangular display region, having a larger inclination angle than a non-corner portion gentle slope at a non-corner portion of the rectangular display region.

5: The display device according to claim 4,
wherein the gap between the first partition and the second partition at the corner portion of the rectangular display region is narrower than the gap between the first partition and the second partition at the non-corner portion of the rectangular display region.

6: The display device according to claim 4,
wherein the gap between the first partition and the second partition at the corner portion of the rectangular display region is wider than the gap between the first partition and the second partition at the non-corner portion of the rectangular display region.

7: The display device according to claim 6,
wherein the gap between the first partition and the second partition at the corner portion of the rectangular display region is wider than the gap between the first partition and the second partition at the non-corner portion of the rectangular display region, with the second partition protruding outward at the corner portion of the rectangular display region.

8: The display device according to claim 4,
wherein an inner side wall surface of the second partition facing the first partition has a larger inclination angle than the outer side wall surface of the first partition.

9: The display device according to claim 4,
wherein the second partition is taller than the first partition.

10: A display device comprising:
a sealing layer, configured to seal a light emitting layer, doubly enclosed at an end portion by a first partition and a second partition that is formed more on an outer side than the first partition with a gap in between,
wherein an outer side wall surface of the first partition facing the second partition is formed as a gentle slope with an inclination angle smaller than an inclination angle of an inner side wall surface of the first partition on a side opposite to the second partition, and
the gap between the first partition and the second partition at a corner portion of a rectangular display region is narrower than the gap between the first partition and the second partition at a non-corner portion of the rectangular display region.

11: The display device according to claim 10,
wherein an inner side wall surface of the second partition facing the first partition has a larger inclination angle than the outer side wall surface of the first partition.

12: The display device according to claim 10,
wherein the second partition is taller than the first partition.

13: A display device comprising:
a sealing layer, configured to seal a light emitting layer, doubly enclosed at an end portion by a first partition and a second partition that is formed more on an outer side than the first partition with a gap in between,
wherein an outer side wall surface of the first partition facing the second partition is formed as a gentle slope with an inclination angle smaller than an inclination angle of an inner side wall surface of the first partition on a side opposite to the second partition, and
the gap between the first partition and the second partition at a corner portion of a rectangular display region is wider than the gap between the first partition and the second partition at a non-corner portion of the rectangular display region.

14: The display device according to claim 13,
wherein an inner side wall surface of the second partition facing the first partition has a larger inclination angle than the outer side wall surface of the first partition.

15: The display device according to claim 13,
wherein the second partition is taller than the first partition.

16: The display device according to claim 13,
wherein the gap between the first partition and the second partition at the corner portion of the rectangular display region is wider than the gap between the first partition and the second partition at the non-corner portion of the rectangular display region, with the second partition protruding outward at the corner portion of the rectangular display region.
